(19) United States
(12) Patent Application Publication
(10) Pub. No.: US 2008/0315210 A1
(43) Pub. Date: Dec. 25, 2008

(54) High electron mobility transistor

(75) Inventors: Hiroaki Ohta, Kyoto (JP); Hirotaka Otake, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto-fu (JP)

(21) Appl. No.: 12/213,110

(22) Filed: Jun. 13, 2008

(30) Foreign Application Priority Data
Jun. 15, 2007 (JP) 2007-159395

(51) Int. Cl. H01L 29/778

(52) U.S. Cl. 257/76; 257/194; 257/E29.246

(57) ABSTRACT

A GaN-based semiconductor layer is stacked on a GaN-based single-crystal substrate. The GaN-based single-crystal substrate forms an electron transit layer, and the GaN-based semiconductor layer forms an electron supply layer. A principal growth plane of the GaN-based single-crystal substrate is an m-plane, and a principal growth plane of the GaN-based semiconductor layer formed on the GaN-based single-crystal substrate is also an m-plane. With such a layer structure, no piezoelectric field is generated since the m-plane is a nonpolar plane. This suppresses generation of a two-dimensional electron gas layer at the time when no gate voltage is applied and consequently enables achievement of a normally-off configuration.

### CROSS REFERENCE TO RELATED APPLICATIONS AND INCORPORATION BY REFERENCE

This application is based upon and claims the benefit of prior Japanese Patent Application P2007-159395 filed on Jun. 15, 2007; the entire contents of which are incorporated by reference herein.

### BACKGROUND OF THE INVENTION

1. Field of the Invention

The present invention relates to a GaN-based high electron mobility transistor (HEMT), which is a kind of field-effect transistor and capable of providing high-speed switching and high sensitivity.

2. Description of the Related Art

In a GaN-based high electron mobility transistor (HEMT) using a GaN-based III-V compound semiconductor, such as GaN or AlGaN, on-resistance during operation is smaller by one digit or more than that in a HEMT using Si, GaAs or the like. Thus, the GaN-based HEMT has drawn attention as a high withstand voltage device that enables a high-temperature operation or a large-current operation.

As described in, for example, “Mou hikaru dakejyanai, kiki-shinnka no ura ni GaN (No Longer Just Emitting Light, GaN Supports Device Evolution)” authored by Satoshi Okubo, Jun. 5, 2006, Nikkei Electronics, pp. 51-60 (hereinafter, referred to as Non-patent Document 1), the above GaN-based high electron mobility transistor has a structure in which a GaN layer and an n-type AlGaN layer are sequentially stacked on a SiC substrate, and in which a source electrode, a gate electrode and a drain electrode are arranged in parallel.

The reason why the high electron mobility transistor, which is a kind of field-effect transistor, can provide high-speed switching and high sensitivity is as follows. Since different kinds of semiconductor materials having different band gaps are bonded together in the high electron mobility transistor, a two-dimensional electron gas layer is generated around an interface therebetween to serve as a flow passage for electrons. The two-dimensional electron gas layer is an extremely thin layer in which free electrons with high mobility are spread, and allows the electrons to move faster than in a normal semiconductor layer. In the structure described in Non-patent Document 1, a two-dimensional electron gas exists in the GaN layer near the boundary with the n-type AlGaN layer.

However, although enabling the provision of the high-speed operation, the high sensitivity and the like as described above, the existence of the two-dimensional electron gas has the problem of causing a normally-on state, in which the two-dimensional electron gas layer is generated to turn the transistor on even if no voltage is applied to the gate electrode. Specifically, a GaN-based semiconductor layer included in the transistor is grown in a direction along the c-axis. However, GaN has a wurtzite structure, having no symmetry in the c-axis direction, and accordingly a c-plane grown GaN epitaxial film has two distinct sides. Thus, at the interface between the n-type AlGaN layer and the GaN layer, a piezoelectric effect due to lattice distortion therein causes a piezoelectric field. The piezoelectric field eventually causes the two-dimensional electron gas layer and the normally-on state.

FIG. 7 is a schematic view of an energy band structure including a conduction band and a valence band at a junction surface between an AlGaN layer and a GaN layer (for more details, see FIGS. 10 and 11 to be described later). FIG. 7 shows the case where no voltage is applied to the gate (gate voltage=0). Even if the gate voltage is 0, a two-dimensional electron gas is generated so much as to greatly extend into the conduction band, and, as a result, facilitates flow of electrons between the AlGaN layer and the GaN layer.

The transistor with the normally-on configuration as described above cannot be applied to various devices. Thus, it has been demanded to implement a normally-off configuration where the transistor is kept turned off unless a voltage is applied to the gate electrode. Therefore, as described in Non-patent Document 1, a structure such as a recess structure in which a portion near the gate electrode is locally thinned in the AlGaN layer has been proposed. However, since such a structure requires processes such as digging the AlGaN layer deeply to install the gate electrode therein and the securing of accuracy thereof, provision of the normally-on configuration has required time and effort.

### SUMMARY OF THE INVENTION

The present invention has been made to solve the foregoing problems. It is an object of the present invention to provide a high electron mobility transistor with a normally-off configuration achieved by a simple method.

In order to achieve the foregoing object, an aspect of the invention according to claim 1 is a high electron mobility transistor in which a GaN-based semiconductor layer is stacked on a GaN-based substrate, and in which a principal growth plane of the GaN-based semiconductor layer is an m-plane.

Another aspect of the invention according to claim 2 is the high electron mobility transistor according to claim 1, wherein the GaN-based substrate is a single-crystal substrate.

Still another aspect of the invention according to claim 3 is the high electron mobility transistor according to claim 2, wherein stacking faults are not more than 10³ cm⁻¹.

According to the present invention, since the m-plane is set as the principal growth plane of the GaN-based semiconductor layer and the m-plane is a nonpolar plane, no piezoelectric field is generated. This suppresses generation of a two-dimensional electron gas layer at the time when no gate voltage is applied and consequently enables achievement of a normally-off configuration. Moreover, since the GaN-based single-crystal substrate whose principal plane is an m-plane is used as the substrate for growth, the GaN-based semiconductor layer having a substantially dislocation-free and even surface can be formed on the GaN-based single-crystal substrate, and thus a high-performance high electron mobility transistor can be implemented.

### BRIEF DESCRIPTION OF THE DRAWINGS

FIG. 1 shows a basic stacked structure of a high electron mobility transistor of the present invention.

FIG. 2 shows a more specific structure of the high electron mobility transistor of the present invention.

FIG. 3 shows a unit cell showing plane directions in a hexagonal system.

FIG. 4 is a schematic view of a band structure at a junction interface between an AlGaN layer and a GaN layer in the case where an m-plane is set as a principal growth plane.

FIG. 5 is an electron microscope photograph showing a cross-section along an a-plane of a structure obtained by crystal growth of undoped GaN on an m-plane of a SiC substrate.

FIG. 6 is another electron microscope photograph showing a cross-section along the a-plane of a stacked body obtained by crystal growth of a GaN-based semiconductor layer on an m-plane of a GaN-based single-crystal substrate.

FIG. 7 is a schematic view of a band structure at the junction interface between an AlGaN layer and a GaN layer in a structure whose principal growth plane is a c-plane.

FIG. 8 is a simulation diagram showing a band structure in a region near the junction interface under the condition that no voltage is applied to the gate in a structure as shown in FIG. 2 where an n-type AlGaN layer is formed on an m-plane of a single-crystal undoped GaN substrate.

FIG. 9 is a simulation diagram showing a band structure in a region near the junction interface under the condition that a voltage is applied to the gate in a structure as shown in FIG. 2 where the n-type AlGaN layer is formed on the m-plane of the single-crystal undoped GaN substrate.

FIG. 10 is a simulation diagram showing a band structure in a region near the junction interface under the condition that no voltage is applied to the gate in a structure as shown in FIG. 2 where the n-type AlGaN layer is formed on a c-plane of the single-crystal undoped GaN substrate.

FIG. 11 is a simulation diagram showing a band structure in a region near the junction interface under the condition that a voltage is applied to the gate in a structure as shown in FIG. 2 where the n-type AlGaN layer is formed on the c-plane of the single-crystal undoped GaN substrate.

### DESCRIPTION OF THE EMBODIMENTS

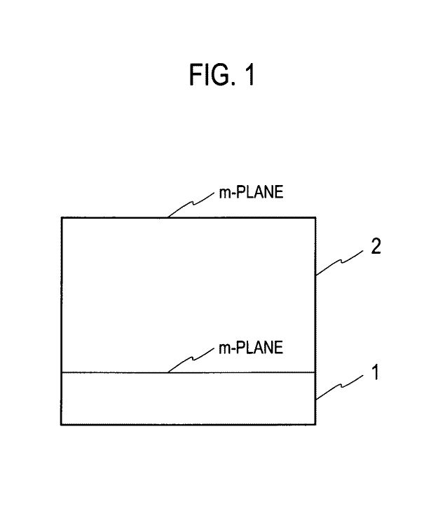

With reference to the drawings, an embodiment of the present invention will be described below. FIG. 1 shows a basic stacked structure of a high electron mobility transistor of the present invention.

For the high electron mobility transistor of the present invention, a Ill-V GaN-based semiconductor that is a hexagonal compound semiconductor is used. The III-V GaN-based semiconductor is expressed by quaternary mixed crystal AlₓGa_{y}In_{z}N (x+y+z=1, 0≦x≦1, 0≦y≦1, 0≦z≦1).

A GaN-based semiconductor layer 2 is stacked on a GaN-based single-crystal substrate 1. The GaN-based single-crystal substrate 1 includes an electron transit layer, and the GaN-based semiconductor layer 2 includes an electron supply layer. As shown in FIG. 1, a principal growth plane of the GaN-based single-crystal substrate 1 is an m-plane, and a principal growth plane of the GaN-based semiconductor layer 2 formed on the GaN-based single-crystal substrate 1 is also an m-plane.

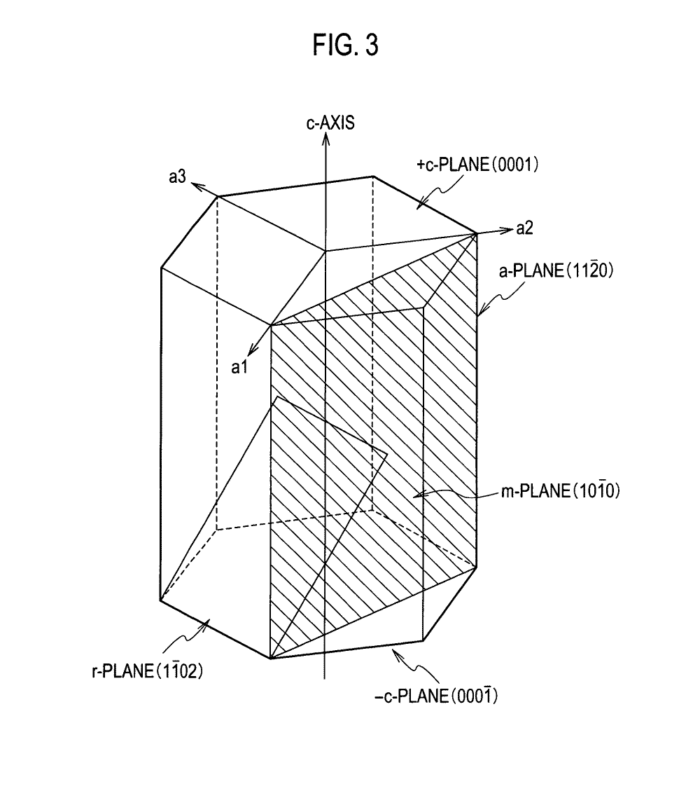

FIG. 3 is a schematic view showing a unit cell in a crystal structure of a GaN-based semiconductor. The crystal structure of a GaN-based semiconductor can be approximated by a hexagonal system. Planes whose normal is the c-axis extending along an axial direction of the hexagonal prism (top and bottom faces of the hexagonal prism) are c-planes (0001). In the GaN-based semiconductor, a polarization direction is along the c-axis. Accordingly, the c-plane in a+c-axis side shows different properties from the c-plane in a−c-axis side, and thus the c-planes are called polar planes. Meanwhile, each of side faces (prismatic planes) of the hexagonal prism is an m-plane (10-10), and each plane passing through a pair of edge lines not adjacent to each other is an a-plane (10-20). These planes are crystal planes perpendicular to the c-planes and extend perpendicularly to the polarization direction. Accordingly, each of the m-planes and a-planes is a plane having no polarity, and thus called a nonpolar plane.

As shown in FIG. 1, when the m-plane, which is a nonpolar plane, is set as the principal growth plane, no piezoelectric field is generated at a junction interface between the electron transit layer (the GaN-based single-crystal substrate 1) and the electron supply layer (the GaN-based semiconductor layer 2), which are formed of different kinds of semiconductor materials having different band gaps. Thus, a normally-off configuration is successfully achieved.

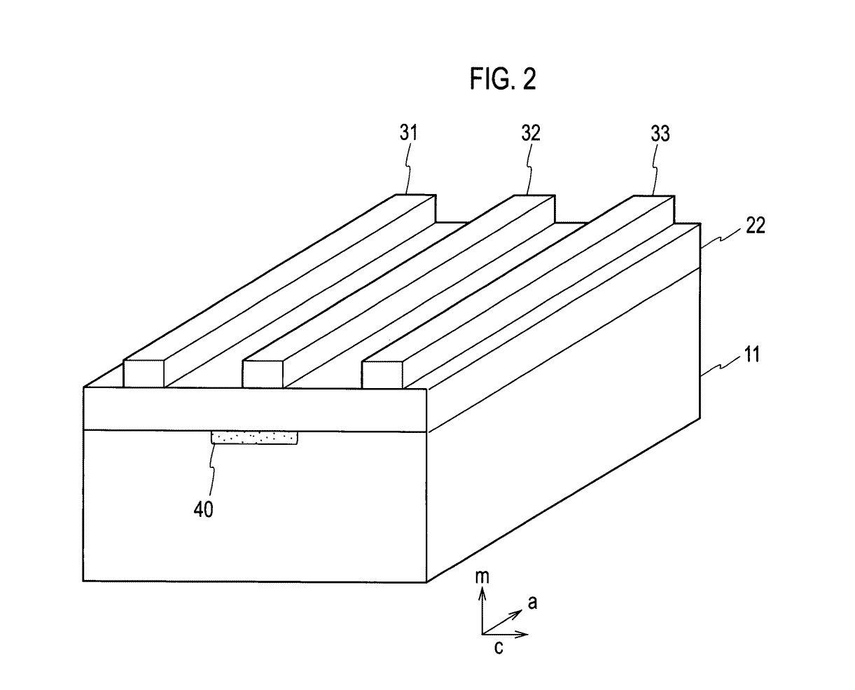

FIG. 2 shows a more specific structure of the high electron mobility transistor using the configuration shown in FIG. 1. As compared with the structure shown in FIG. 1, a single-crystal undoped GaN substrate 11 is used as the GaN-based single-crystal substrate 1 and an n-type AlGaN layer 22 is used as the GaN-based semiconductor layer 2. The undoped GaN substrate 11 is formed to have a thickness of approximately 1 μm, and the AlGaN layer 22, which is doped with Si by 10¹⁷ to 10¹⁸ and has a thickness of about 20 nm, is grown on the m-plane of the undoped GaN substrate 11. An Al ratio of the n-type AlGaN layer 22 is set to about 20% to 30%. Here, the undoped GaN substrate 11 corresponds to the electron transit layer and the n-type AlGaN layer 22 corresponds to the electron supply layer. Meanwhile, a source electrode 31, a gate electrode 32 and a drain electrode 33 are formed on the n-type AlGaN layer 22. A region 40 represents a two-dimensional electron gas layer generated when a positive voltage is applied to the gate electrode 32. Moreover, as the GaN-based single-crystal substrate 1, a p-type GaN substrate 11 may be used instead of the undoped GaN substrate 11 because the undoped GaN substrate is undesirably slightly n-type.

When the n-type AlGaN layer 22 is crystal-grown on the undoped GaN substrate 11 whose principal plane is an m-plane, the principal growth plane of the n-type AlGaN layer 22 also becomes an m-plane. Thus, no piezoelectric field is generated at a junction interface between the undoped GaN substrate 11 and the n-type AlGaN layer 22. This makes it possible to suppress generation of the two-dimensional electron gas 40 when no voltage is applied to the gate electrode 32.

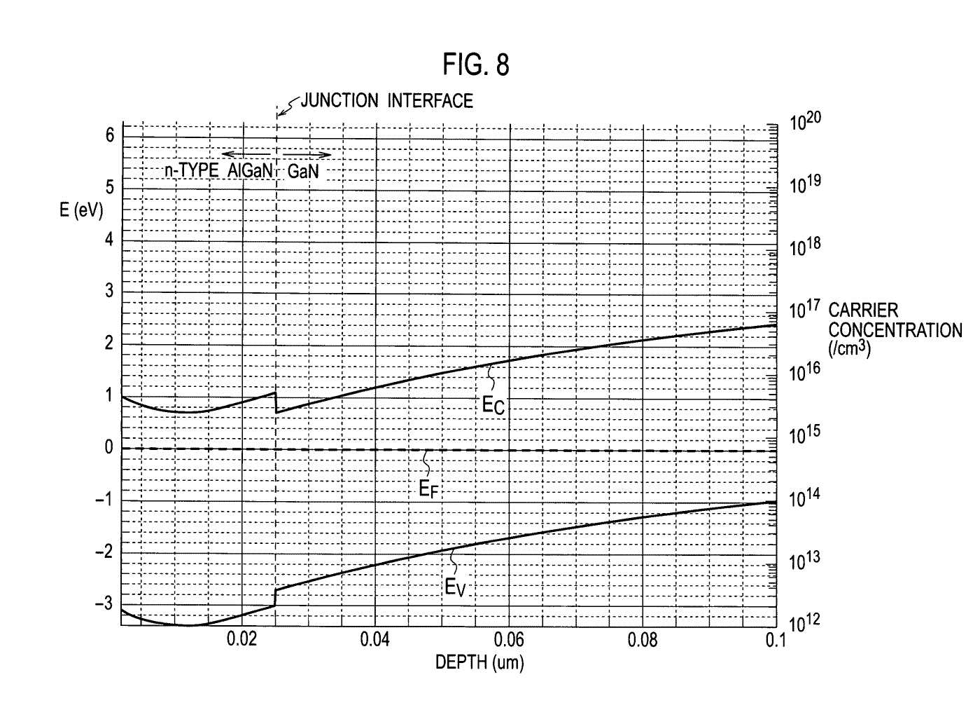

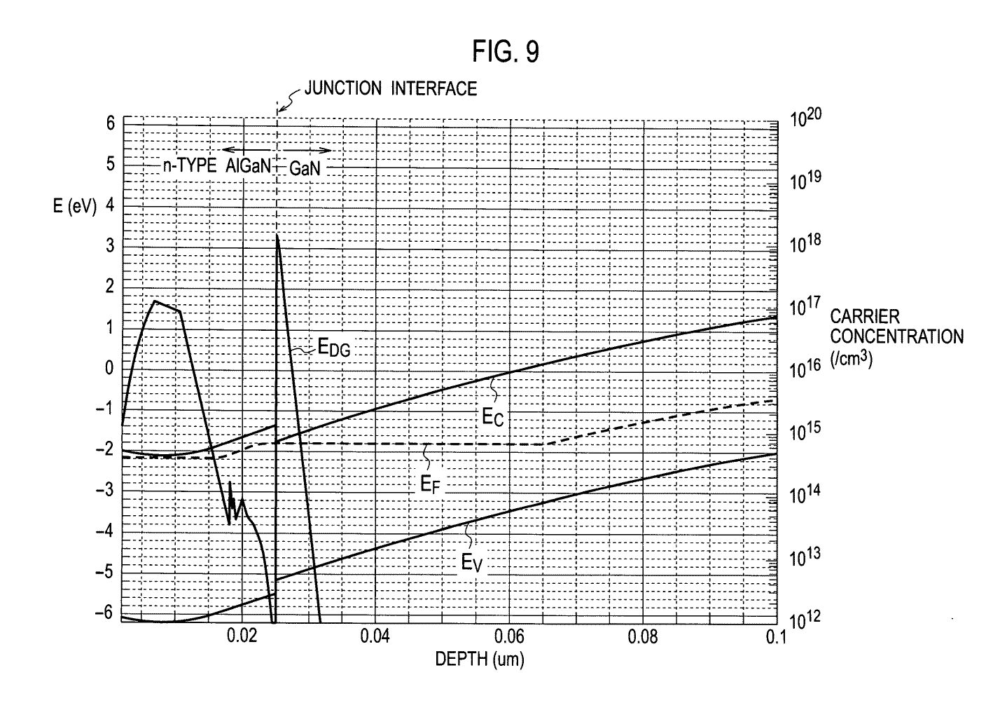

FIG. 4 is a schematic view of an energy band structure including a conduction band and a valence band at the junction interface between the AlGaN layer and the GaN layer in the case where the m-plane is set as the principal growth plane (for more details, see FIGS. 8 and 9 to be described later). FIG. 4 shows the case where no voltage is applied to the gate electrode 32, and the two-dimensional electron gas indicated by a dotted line appears when a voltage is applied to the gate electrode 32. When no voltage is applied to the gate electrode 32, a Fermi level, although not shown, exists below the energy band of the conduction band and accordingly no two-dimensional electron gas is generated. This means that the transistor is set in an off state with no voltage and that a normally-off configuration is successfully achieved. On the other hand, when a voltage is applied to the gate electrode 32, the energy band of the conduction band at the junction interface comes closer to the Fermi level, and accordingly, the two-dimensional electron gas is generated as indicated by the dotted line. Thus, the transistor is set in an on state with the voltage.

Next, description will be given of a method for manufacturing the high electron mobility transistor shown in FIG. 2. First, a single-crystal undoped GaN substrate 11 whose principal plane is an m-plane can be prepared by cutting out of a GaN single crystal substrate whose principal plane is a c-plane. The m-plane of the cut-out substrate is polished by, for example, chemical mechanical polishing such that an azimuth error between the <0001>axis direction and the <11-20> axis direction falls within ±1° (preferably within ±0.3°). In this way, the undoped GaN substrate 11 whose principal plane is an m-plane and having no crystal defects such as dislocation and stacking faults is obtained. On a surface of such a GaN-based single-crystal substrate, atomic-level steps are merely generated.

Next, by use of a MOCVD method, an n-type AlGaN layer 22 is formed on the undoped GaN substrate 11 whose principal plane is an m-plane. The undoped GaN substrate 11 is transported into a growth chamber of a MOCVD device and then heated by a heater until a substrate temperature reaches 1000° C. to 1100° C. Thereafter, ammonia serving as a nitrogen source gas, trimethylaluminum serving as an aluminum source gas, trimethylgallium serving as a gallium source gas, and silane serving as a source gas of n-type dopant Si (silicon) are supplied together with a carrier gas. As a result, the n-type AlGaN layer 22 doped with silicon is grown on the undoped GaN substrate 11.

Finally, a source electrode 31, a gate electrode 32 and a drain electrode 33 are formed in a stripe pattern by metal deposition, and thus the high electron mobility transistor shown in FIG. 2 is completed. As indicated by arrows in FIG. 2, while the crystal growth direction is the m-axis direction, the source electrode 31, the gate electrode 32 and the drain electrode 33 are formed such that the arrangement direction thereof can be parallel to the c-axis direction and that the stripe direction (longitudinal direction) of each electrode can be parallel to the a-axis direction.

Meanwhile, the n-type AlGaN layer 22 is grown to be formed on the single crystal undoped GaN substrate 11 under the condition that V/III ratio is maintained at a high value of 3000 or more, where the V/III ratio is a ratio of a molar fraction of a nitrogen source (ammonia) to that of a gallium source (trimethylgallium). Such a high V/III ratio has been employed for growth of the GaN crystal on the c-plane serving as a principal plane, but has not reported to be employed for growth of a group-III nitride semiconductor layer on a principal plane other than the c-plane.

In the above embodiment, the n-type AlGaN layer 22 whose principal plane is an m-plane is grown evenly and dislocation-free under the condition that such a high V/III ratio is employed and that no buffer layer is interposed between the single-crystal undoped GaN substrate 11 and the n-type AlGaN layer 22.

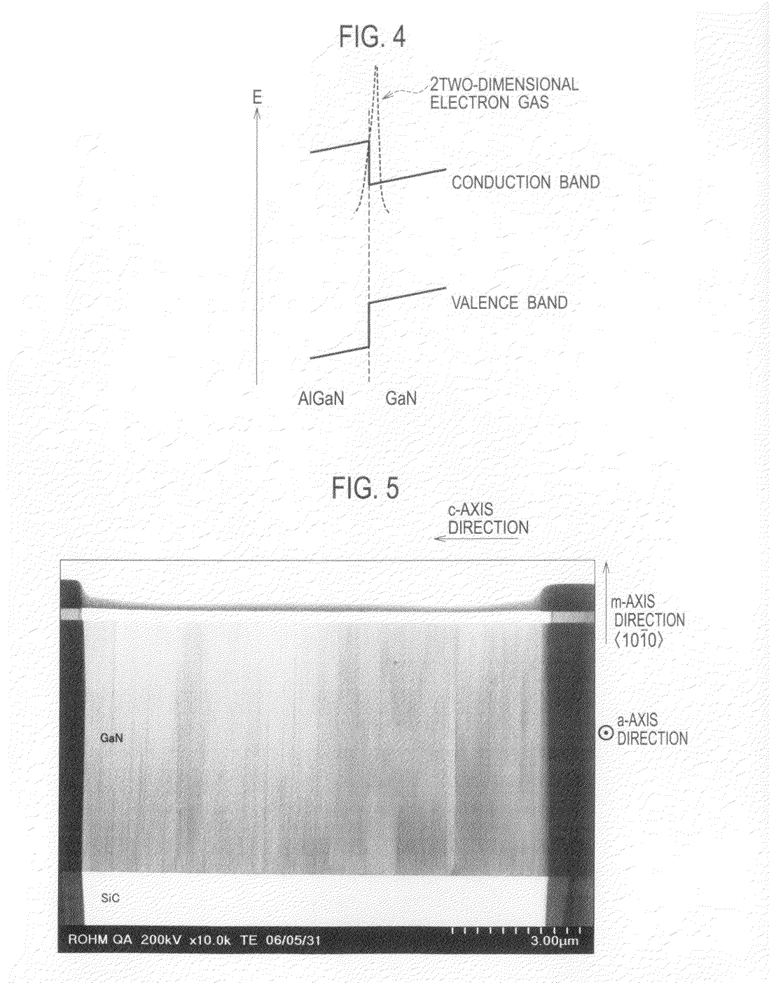

FIG. 5 is an electron microscope (STEM: scanning transmission electron microscope) photograph showing a cross-section along an a-plane of a structure obtained by crystal growth of undoped GaN on an m-plane of a SiC substrate instead of the GaN-based single-crystal substrate. The lateral direction in the photograph shown in FIG. 5 is parallel to the c-axis. In FIG. 5, striations indicating presence of dislocation appear, which shows countless numbers of stacking faults have occurred.

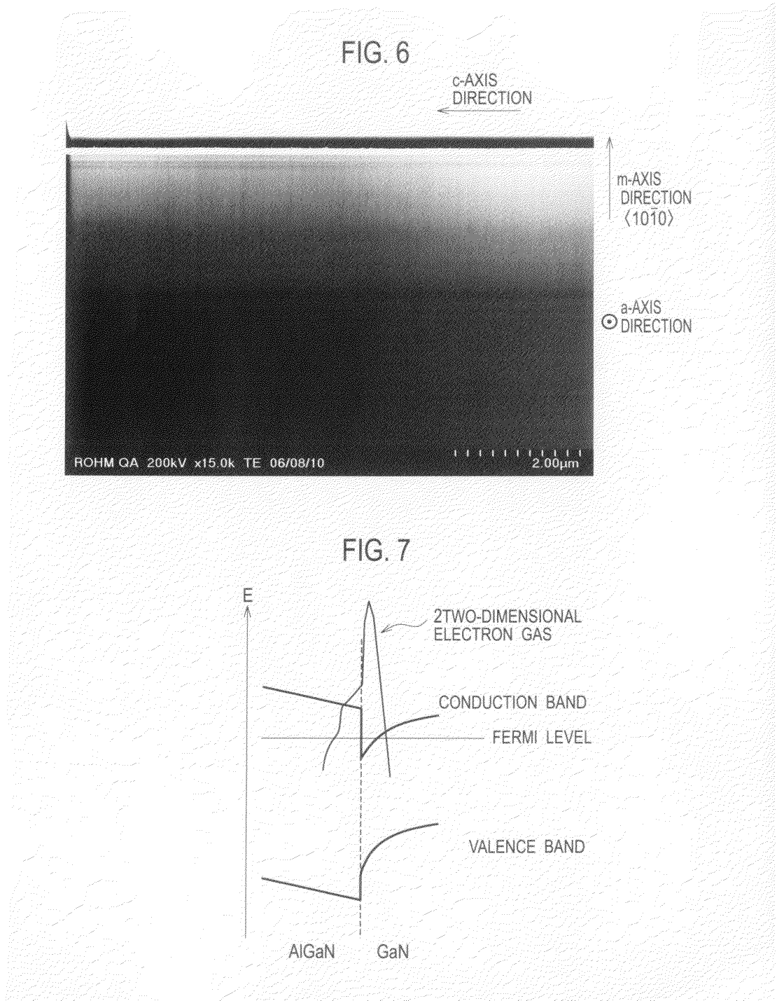

On the other hand, FIG. 6 is another electron microscope (STEM) photograph showing a cross-section of a stacked body along an a-plane, as in the case of FIG. 5. The stacked body is formed by sequentially stacking an n-type GaN layer, InGaN/GaN layers (5 cycles), a GaN final barrier layer, a p-type AlGaN electron stopping layer and a p-type GaN layer on the m-plane of the GaN-based single-crystal substrate. The lateral direction in the photograph is parallel to the c-axis. Note that the layers including a GaN compound semiconductor formed on the GaN-based single-crystal substrate are grown under the condition that a V/III ratio is maintained at a high value of 3000 or more, where the V/III ratio is a ratio of a molar fraction of a nitrogen source (ammonia) to that of a gallium source (trimethylgallium) as described above.

In FIG. 6, no striation indicating presence of dislocation is observed and an interface between the GaN-based single-crystal substrate, and the n-type GaN layer formed thereon is unrecognizable. This shows that the m-plane GaN-based semiconductor layer 2 having an even and dislocation-free surface is successfully grown, and that a low V/III ratio, which has heretofore been considered required, is not actually required in the case. As is clear from the result, in the high electron mobility transistor having the configuration shown in FIG. 2, the n-type AlGaN layer 22 having an even and dislocation-free surface is formed on the m-plane of the single-crystal undoped GaN substrate 11.

Note, however, that an off-angle of the principal plane of the single-crystal undoped GaN substrate 11 must be controlled within the range described above. For example, in the case where the GaN-based semiconductor layer is grown on the m-plane GaN-based single-crystal substrate whose m-plane has an off-angle of 2°, the GaN crystal is grown in a terrace pattern. Thus, an flat surface as in the case of the off-angle within ±1° cannot be obtained.

Though the photograph data of FIG. 6 shows that there is no dislocation, in other words, no stacking faults, strictly how many stacking faults actually exist is further checked based on the photograph data shown in FIG. 6. As a result, not even one stacking fault is found at a maximum interval of 10 μm. Therefore, assuming that there is one stacking fault at a minimum interval of 10 μm, the number of stacking faults per 1 cm is 10³. Thus, it can be said that there is substantially no dislocation if the stacking faults are not more than 10³ cm⁻¹.

The high electron mobility transistor having the structure shown in FIG. 2 was manufactured as described above, and characteristics of the transistor were measured. As in the case of FIG. 2, a single-crystal undoped GaN substrate 11 was used and an n-type AlGaN layer 22 is formed on an m-plane of the undoped GaN substrate 11. Here, a residual donor carrier concentration in the undoped GaN substrate 11 was 10¹⁶ to 10¹⁷ cm⁻³. Moreover, an Al composition in the n-type AlGaN layer 22 was set to 25% (Al_{0.25}GaN), n-type impurities Si were doped at 3.5×10¹⁸ cm⁻³, and the donor carrier concentration was set to 10¹⁵ to 10¹⁶ cm⁻³.

FIGS. 8 and 9 each is a simulation diagram of an energy band in a region near the junction interface between the undoped GaN substrate (electron transit layer) and the n-type AlGaN layer (electron supply layer). Specifically, FIG. 8 shows the condition that a gate voltage of 0 volt (V) was applied to the gate electrode 32 while FIG. 9 shows the condition that a gate voltage of 5 V was applied to the gate electrode 32. In both FIGS. 8 and 9, the vertical axis on the left side indicates energy (eV), the vertical axis on the right side indicates a carrier concentration (cm⁻³), and the horizontal axis indicates a distance (μm) in a depth direction. In each of FIGS. 8 and 9, a dotted line E_{F} indicates a Fermi level, a solid curve E_{C} drawn thereabove indicates an energy band of a conduction band, a solid curve E_{V} drawn therebelow indicates an energy band of a valence band, and a solid curve E_{DG} indicates two-dimensional electron gas energy. As can be seen from FIGS. 8 and 9, the thicknesses of the n-type AlGaN layer and the undoped GaN substrate were set to 0.025 μm and 0.075 μm, respectively.

FIG. 8 shows that no two-dimensional electron gas was generated. Moreover, since the band E_{C} of the conduction band was away from the Fermi level E_{F}, no current flew between the n-type AlGaN layer and the undoped GaN substrate. On the other hand, FIG. 9 shows that the band E_{C} of the conduction band in the region near the junction interface came closer to the Fermi level E_{F}, and that accordingly the two-dimensional electron gas energy E_{DG} was generated. Thus, a current flew between the n-type AlGaN layer and the undoped GaN substrate in this case. As described above, FIGS. 8 and 9 show that a normally-off configuration was successfully achieved, in which no current flows when no voltage is applied to the gate electrode 32. This indicates that the m-plane of the single crystal GaN substrate was an flat plane with few crystal defects such as dislocation and stacking faults. Thus, it is found out that on-resistance of the transistor could be significantly reduced.

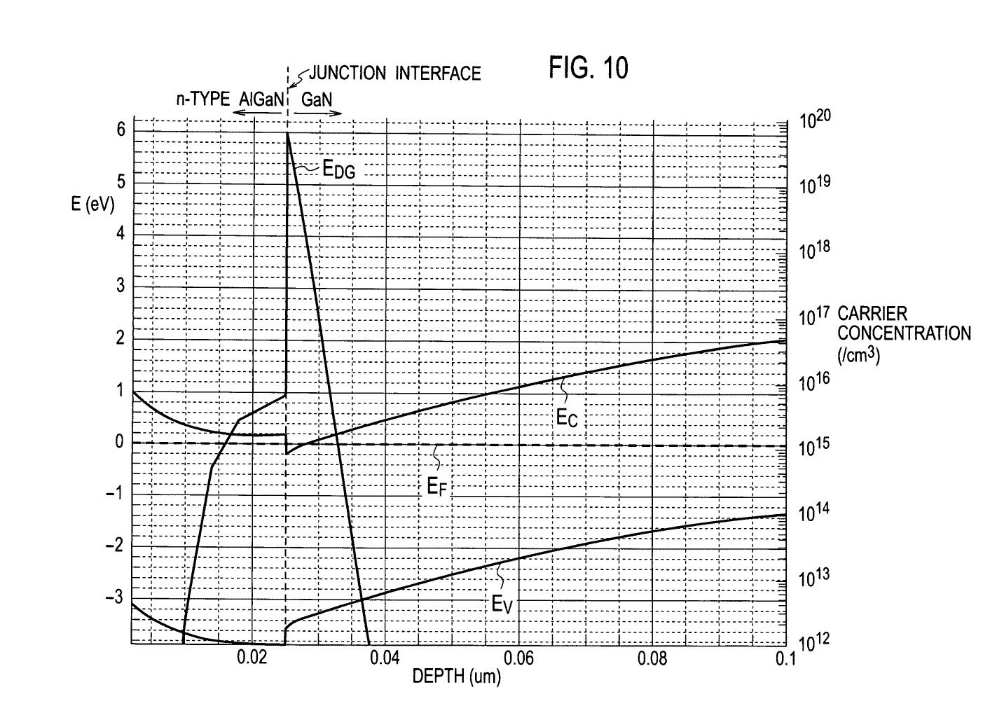

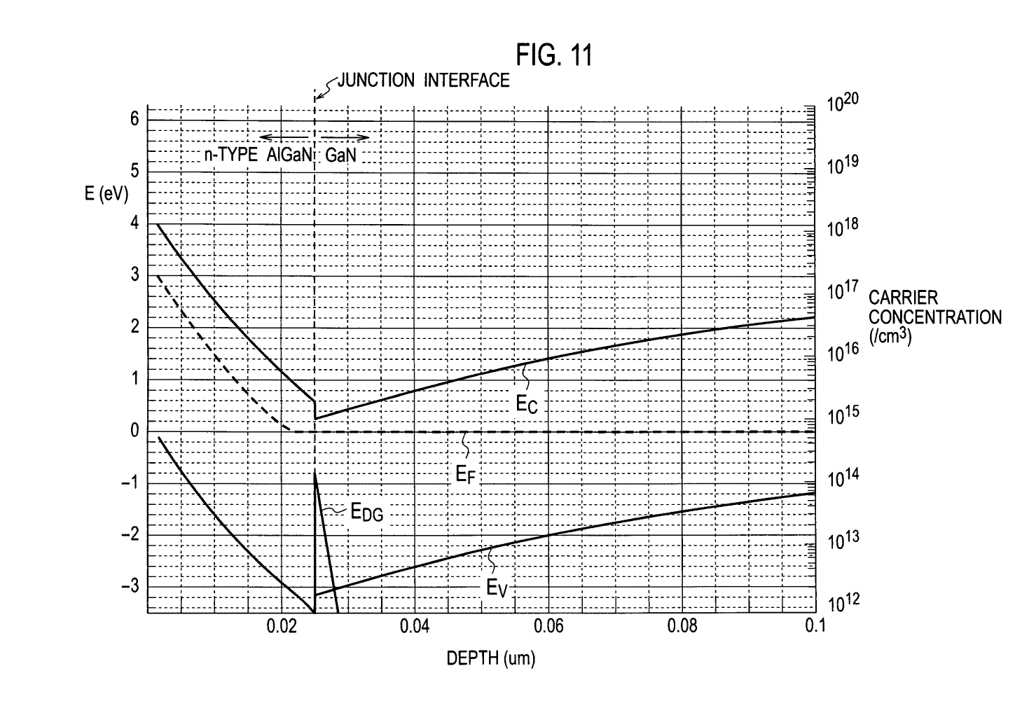

Meanwhile, for comparison to FIGS. 8 and 9, a high electron mobility transistor having the structure shown in FIG. 2 was manufactured, in which the c-plane of the undoped GaN substrate was used as the principal plane and an n-type AlGaN layer 22 was crystal-grown thereon. A residual donor carrier concentration in the undoped GaN substrate, an Al composition ratio of the n-type AlGaN layer, and a donor carrier concentration of impurities Si were set to the same values as FIGS. 8 and 9. FIGS. 10 and 11 each is a simulation diagram of an energy band in a region near the junction interface between the undoped GaN substrate and the n-type AlGaN layer. Specifically, FIG. 10 shows the condition that a gate voltage of 0 volt was applied to the gate electrode while FIG. 11 shows the condition that a gate voltage of −3 V was applied to the gate electrode. Vertical and horizontal axes and reference numerals in FIGS. 10 and 11 indicate the same as those in FIGS. 8 and 9.

FIG. 10 shows that two-dimensional electron gas energy E_{DG} was generated and a band E_{C} of a conduction band in the region near the junction interface fell below the Fermi level E_{F} even though no gate voltage was applied. This means that the transistor was in a normally-on state, in which a current flows between the n-type AlGaN layer and the undoped GaN substrate with no voltage.

Meanwhile, in FIG. 11, which shows a condition that a negative voltage is applied to the gate of this transistor, generation of the two-dimensional electron gas was suppressed, so that a magnitude of the two-dimensional electron gas energy E_{DG} could be significantly reduced. Moreover, the band E_{C} of the conduction band in the region near the junction interface came above the Fermi level E_{F}. This means that the transistor could be set in an off state with the negative voltage. As described above, when the c-plane growth is employed, a negative voltage must be applied to the gate in order to switch the transistor from on to off.

As described above, the use of the m-plane, which is a nonpolar plane, as the principal plane of crystal growth prevents a piezoelectric field from being generated at the interface between the GaN substrate 11 and the n-type AlGaN layer 22. Thus, when no voltage is applied to the gate electrode, generation of the two-dimensional electron gas 40 is suppressed and thus a normally-off configuration is successfully achieved. Moreover, the use of the m-plane as the principal plane of crystal growth enables extremely stable growth of a group-III nitride semiconductor crystal, and can improves crystallinity. This makes it possible to manufacture a high-performance high electron mobility transistor.

Meanwhile, if defects are caused at the growth interface between the GaN substrate 11 serving as the electron transit layer and the n-type AlGaN layer 22 serving as the electron supply layer, a hysteresis phenomenon occurs in current-voltage characteristics between the source and the drain since these defects have a function of trapping electrons. Accordingly, there occurs deterioration in the current-voltage characteristics, such as reduction in a drain current.

In the present invention, since a GaN-based single-crystal substrate is used as the GaN substrate 11, the n-type AlGaN layer 22 can achieve high-quality crystallinity with few defects. Furthermore, by growing the n-type AlGaN layer 22, which is a GaN-based semiconductor layer, on the GaN-based single-crystal substrate having substantially no dislocation, the n-type AlGaN layer 22 can be formed to achieve good crystallinity without stacking faults or threading dislocation originating from a regrowth plane (m-plane) of the GaN-based single-crystal substrate. Therefore, deterioration in the current-voltage characteristics such as reduction in the drain current attributable to the above defects can also be suppressed, and thus a high-performance high electron mobility transistor can be implemented.

As described above, the present invention includes various embodiments and the like which are not described herein, as a matter of course. Therefore, a technical scope of the present invention is defined only by the following claims pertinent based on the foregoing description.

What is claimed is:

1. A high electron mobility transistor comprising:
a GaN-based substrate; and
a GaN-based semiconductor layer stacked on the GaN-based substrate, wherein
a principal growth plane of the GaN-based semiconductor layer is formed of an m-plane.

2. The high electron mobility transistor of claim 1, wherein
the GaN-based substrate is a single-crystal substrate.

3. The high electron mobility transistor of claim 2, wherein
stacking faults are not more than 10³ cm⁻¹.
